(19) United States
(12) Patent Application Publication
(10) Pub. No.: US 2026/0304882 A1
(43) Pub. Date: Oct. 1, 2026

(54) SEMICONDUCTOR DEVICE AND METHOD OF MANUFACTURING SEMICONDUCTOR DEVICE

(71) Applicant: Taiwan Semiconductor Manufacturing Company, Ltd., Hsinchu (TW)

(72) Inventors: Meng-Ju SHE, Hsinchu (TW); Tsung-Chieh HSIAO, Hsinchu (TW); Wei-Yuan LEE, Hsinchu (TW); Chih-Lin WANG, Hsinchu (TW)

(73) Assignee: Taiwan Semiconductor Manufacturing Company, Ltd., Hsinchu (TW)

(21) Appl. No.: 19/092,573

(22) Filed: Mar. 27, 2025

(51) Int. Cl. H10D 64/01; H01L 21/321; H10D 84/83

(52) U.S. Cl. CPC H10D 64/017; H10D 84/83138; H10P 52/403

(57) ABSTRACT

An embodiment semiconductor device includes a substrate, a first plurality of functional gate structures within a first circuit area over the substrate, a first plurality of dummy gate structures adjacent to the first circuit area over the substrate, a second plurality of functional gate structures within a second circuit area over the substrate, and a second plurality of dummy gate structures adjacent to the second circuit area over the substrate. The first average height and the second average height are different.

### BACKGROUND

Integrated circuits are formed using various processing steps. Some processing steps involve depositing one or more layers of materials (e.g., a dielectric, a metal, an alloy, a composite, or a combination thereof) on a semiconductor wafer. The deposition processes result in an intermediate structure and/or non-planar surfaces, in some instances. The intermediate structure and/or non-planar surfaces are polished to remove excess materials and/or to provide a more uniform surface for additional processing. In some instances, the polishing is performed by a chemical mechanical polishing (CMP) process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of a chemical mechanical polishing (CMP) system, in accordance with some embodiments.

FIG. 2A is a simplified top or plan view of a portion of a semiconductor device, in accordance with some embodiments.

FIG. 2B is a simplified cross-sectional view of the semiconductor device in FIG. 2A, in accordance with some embodiments.

FIG. 3 is an enlarged cross-sectional view of a dummy gate structure, in accordance with some embodiments.

FIG. 4 is a simplified top or plan view of a portion of another semiconductor device, in accordance with some embodiments.

FIG. 5 is a flowchart of a method of manufacturing a semiconductor device, in accordance with some embodiments.

FIG. 6 is a block diagram of an electronic design automation (EDA) system, in accordance with some embodiments.

FIG. 7 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

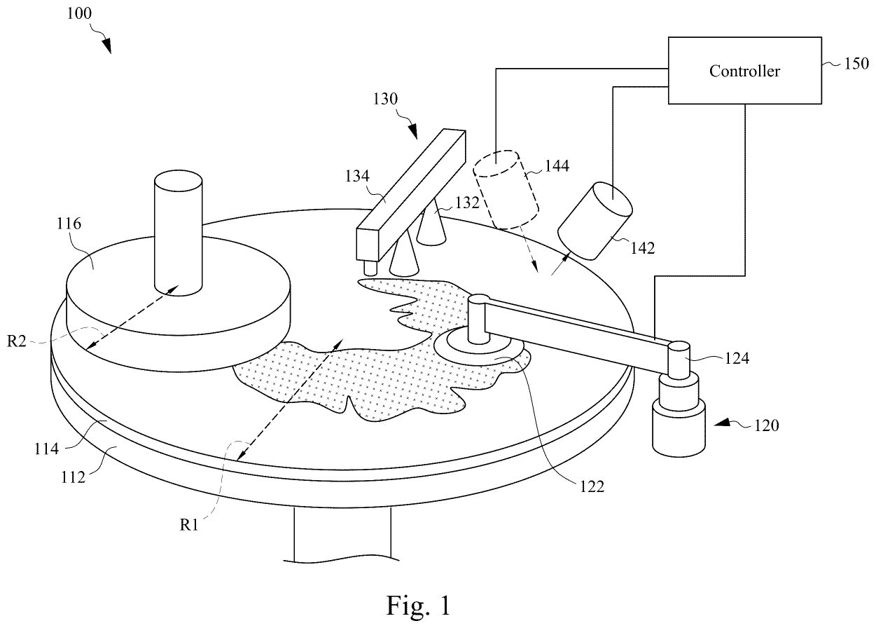

A chemical mechanical polishing (CMP) process is performed to planarize (also referred to as to polish) a surface of a semiconductor device. A CMP system uses a combination of chemical reactions and mechanical grinding to remove material from the surface of the semiconductor device. FIG. 1 is a diagram of a CMP system 100, in accordance with some embodiments. CMP system 100 includes a platen 112 configured to rotate in at least one direction. A polishing pad 114 is provided on top of platen 112. Polishing head 116 is configured to hold a wafer for processing using CMP system 100. Polishing head 116 is configured to adjust a pressure exerted on the wafer by polishing pad 114.

CMP system 100 further includes a conditioner 120 configured to restore a roughness of polishing pad 114. CMP system 100 further includes a slurry delivery system 130 configured to deliver a slurry to polishing pad 114 to facilitate removal of material from the wafer. A sensor 142 is used to monitor the roughness of polishing pad 114. In some embodiments, sensor 142 is configured to receive light emitted by a light emitter integrated with sensor 142 and reflected by a surface of polishing pad 114. In some embodiments, sensor 142 is configured to receive light emitted by an external light emitter (e.g., a light emitter 144) and reflected by the surface of polishing pad 114. In addition, CMP system 100 includes a controller 150 configured to receive information from sensor 142 and control conditioner 120 based on the received information. In some embodiments, controller 150 is configured to control an internal light emitter integrated with sensor 142 and/or an external light emitter 144.

CMP system 100 removes material from the wafer based on relative motion between polishing pad 114 and polishing head 116 (on which the wafer is held) and based on chemical and mechanical interactions with a slurry introduced to polishing pad 114 by slurry delivery system 130. In some embodiments, the slurry includes a chemical solution and abrasive particles. In some embodiments, the chemical solution reacts with the surface of the wafer to soften the materials on the surface of the wafer. Also, the abrasive particles interact with the surface of the wafer and the mechanical force exerted on the wafer by polishing head 116 against polishing pad 114 to remove the materials on the surface of the wafer.

Platen 112 is configured to rotate in at least a first direction. In some embodiments, platen 112 is configured to rotate in more than one direction. In some embodiments, platen 112 is configured to be held stationary. In some embodiments, platen 112 is configured to have a constant rotational speed. In some embodiments, platen 112 is configured to have a variable rotational speed. In some embodiments, platen 112 is rotated by a motor. In some embodiments, the motor is an alternating current (AC) motor, a direct current (DC) motor, a universal motor, or another suitable motor. In some embodiments, platen 112 is configured to translate in one or more directions.

Polishing pad 114 is disposed on platen 112 so that polishing pad 114 is rotatable along with platen 112 in a same direction at a same speed. In some embodiments where platen 112 is stationary, polishing pad 114 is held stationary. Polishing pad 114 has a textured surface which is configured to remove material from the wafer during operation of CMP system 100.

Polishing head 116 is configured to hold the wafer during operation of CMP system 100. In some embodiments, polishing head 116 includes a retaining ring to secure the wafer against the polishing head 116. In some embodiments, polishing head 116 includes a vacuum to secure the wafer against the polishing head 116. Polishing head 116 is configured to rotate in a second direction. In some embodiments, the second direction is the same as the first direction. In some embodiments, the second direction is opposite the first direction. In some embodiments, polishing head 116 is configured to rotate at a constant rotational speed. In some embodiments, polishing head 116 is configured to rotate at a variable rotational speed. In some embodiments, polishing head 116 is rotated by a motor. In some embodiments, the motor is an AC motor, a DC motor, a universal motor, or another suitable motor. In some embodiments, polishing head 116 is held stationary. In some embodiments, polishing head 116 translates relative to polishing pad 114.

Polishing head 116 is configured to move in a direction perpendicular to the surface of polishing pad 114. By moving polishing head 116 in the direction perpendicular to the surface of polishing pad 114, the pressure exerted on the wafer by polishing head 116 against polishing pad 114 is adjustable. In some embodiments, polishing head 116 includes pressure sensors to monitor a pressure exerted on the wafer. In some embodiments, the pressure sensors are connected to a control system (e.g., controller 150). In some embodiments, polishing head 116 includes pressure adjustment devices configured to exert force on the wafer held therein against polishing pad 114 to adjust the pressure exerted on the wafer at various locations of the wafer. In some embodiments, the pressure adjustment devices include nozzles configured to emit pressurized gas, translatable pins or other suitable force exerting elements.

Polishing pad 114 has a radius R1 extending from the center of platen 112/polishing pad 114 to an exterior edge of polishing pad 114. In some embodiments, radius R1 of polishing pad 114 is at least 2.5 times greater than a radius R2 of polishing head 116.

In some embodiments, during operation of CMP system 100, the roughness of polishing pad 114 decreases as a result of the force between the wafer and polishing pad 114 or through a buildup of slurry or other particles. Conditioner 120 is configured to restore the roughness of polishing pad 114 to maintain effective operation of CMP system 100. In this non-limiting example, conditioner 120 includes a conditioner pad 122 configured to contact polishing pad 114. In some embodiments, conditioner pad 122 is configured to rotate. In this non-limiting example, conditioner 120 also includes a conditioner arm 124 configured to translate conditioner pad 122 across the surface of polishing pad 114.

Slurry delivery system 130 is configured to provide the slurry onto polishing pad 114. In some embodiments, slurry delivery system 130 includes a slurry mixing system configured to mix various fluid compositions prior to delivering the mixture to polishing pad 114. In this non-limiting example, slurry delivery system 130 includes at least one nozzle 132 configured to deliver the slurry to polishing pad 114. In this non-limiting example, slurry delivery system 130 further includes a delivery arm 134 configured to translate a location of nozzle 132 relative to the surface of polishing pad 114.

Sensor 142 is configured to collect information related to the roughness of polishing pad 114. A single sensor 142 is included in FIG. 1 as a non-limiting example. In some embodiments, multiple sensors are deployed to detect the roughness at different locations on polishing pad 114. In some embodiments, sensor 142 is an integrated array of sensing elements extending across a portion of polishing pad 114. By collecting information from sensor 142 on roughness at different locations, controller 150 would be able to more precisely locate portions of polishing pad 114 having a roughness outside of a threshold range. In some embodiments, sensor 142 is an optical sensor configured to receive light reflected from the surface of polishing pad 114. In some embodiments, sensor 142 is sensitive to visible light. In some embodiments, sensor 142 is sensitive to infrared (IR) light. In some embodiments where multiple sensors are deployed in CMP system 100, each sensor of the multiple sensors corresponds to visible light detecting sensor. In some embodiments where multiple sensors are deployed in CMP system 100, at least one sensor of the multiple sensors is different from another sensor (e.g., one sensor is sensitive to visible light and one sensor is sensitive to IR light). In some embodiments, sensor 142 includes an internal light emitter integrated therein for emitting light onto the surface of polishing pad 114. In some embodiments, sensor 142 is configured to receive light emitted by an external light emitter (e.g., light emitter 144) and reflected by the surface of polishing pad 114.

As polishing pad 114 and polishing head 116 rotate, a location of detection point(s) for sensor 142 relative to the polishing pad 114 changes. By using multiple distinct detection points, the collected data is more uniformly distributed across polishing pad 114. The uniformly distributed data enables a more accurate determination of a roughness profile of polishing pad 114. A roughness profile is a variation of roughness across the surface of polishing pad 114. For example, in some embodiments, a region of the polishing pad 114 used most often during the CMP process will have a lowest roughness (and corresponding to a reduced removal capacity or a reduced removal rate).

Controller 150 is configured to receive information from sensor 142. In some embodiments, controller 150 is configured to control the internal light emitter integrated with sensor 142 and/or to control external light emitter 144. In some embodiments, the collected information corresponds to an image of the polishing pad 114. In some embodiments, the collected information indicates a roughness of the polishing pad 114. Controller 150 is configured to determine a roughness profile of polishing pad 114 based on the collected information.

In some embodiments, based on the determined roughness profile of the polishing pad 114, controller 150 is configured to control conditioner 120. In some embodiments, controller 150 controls a number of iterations of a conditioning process of conditioner 120. Controller 150 is also configured to track the iterations of the conditioning process applied to polishing pad 114. In some embodiments, controller 150 is configured to adjust the pressure of conditioner pad 122 on polishing pad 114. In some embodiments, controller 150 is configured to adjust the location of conditioner pad 122 based on the determined roughness profile of polishing pad 114. In some embodiments, controller 150 is configured to control a secondary conditioner (not shown) to increase the number of conditioners used to adjust the roughness of polishing pad 114.

In some embodiments, a semiconductor device includes circuit areas that are formed based on electrically connecting transistors formed on a substrate of the semiconductor device. In some embodiments, the formation of the gate structures of the transistors in the semiconductor device includes depositing one or more layers of gate contact materials followed by a CMP process to remove the excess materials to form the gate structures. In some embodiments, different circuit areas of the semiconductor device are designed for different functionalities, and performance thereof may be further improved or adjustable by configuring the gate structures to have different gate heights.

In some applications, applying one CMP process during manufacture of the gate structures results in the gate structures having a same gate height (with variations within an engineering tolerance, such as less than 0.2 nanometers in some embodiments). In some applications, multiple rounds of masking processes, deposition processes, and CMP processes are performed in order to manufacture the gate structures having different gate heights (corresponding to different gate heights with the difference greater than the engineering tolerance, such as greater than 0.2 nanometers in some embodiments). According to one or more embodiments of the present application, the dummy gate structures adjacent to different circuit areas of different gate heights are configured to have different removal rates under the same CMP process. Accordingly, the gate heights of the gate structures formed by performing a single CMP process are controllable based on configuring the removal rates of the adjacent dummy gate structures under the CMP process.

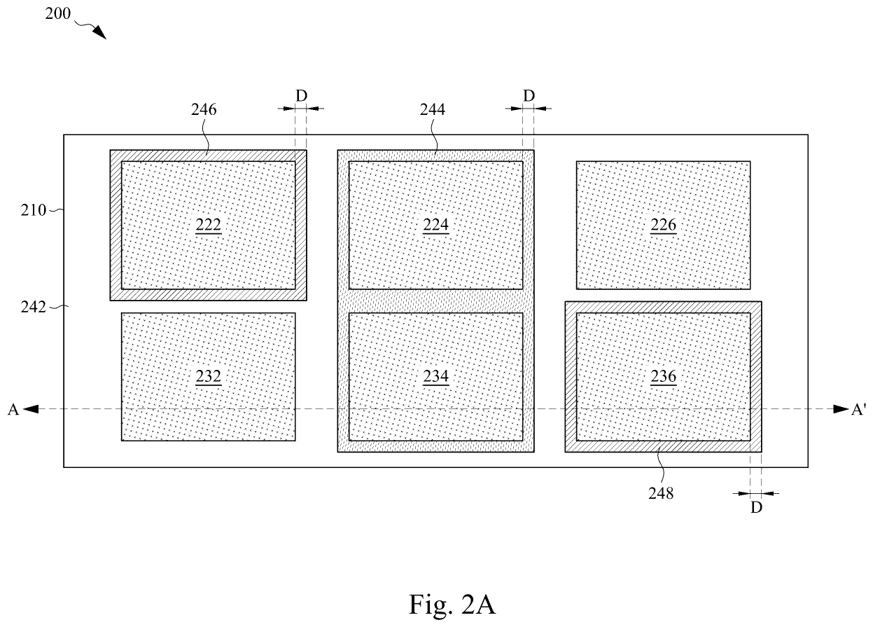

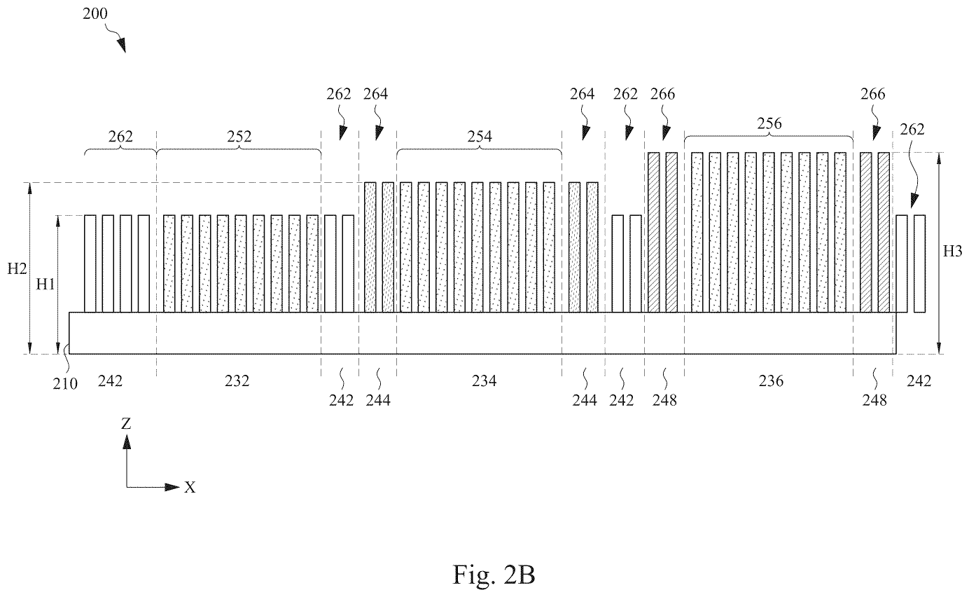

FIG. 2A is a simplified top or plan view of a portion of a semiconductor device 200, in accordance with some embodiments. In FIG. 2A, many features or components are simplified or omitted for simplicity.

In FIG. 2A, semiconductor device 200 includes a substrate 210 and a plurality of gate structures over substrate 210. In this example, the plurality of gate structures is arranged within various areas, including a first circuit area 222, a second circuit area 224, a third circuit area 226, a fourth circuit area 232, a fifth circuit area 234, a sixth circuit area 236, a first dummy area 242, a second dummy area 244, a third dummy area 246, and a fourth dummy area 248. In some embodiments, each one of first circuit area 222, second circuit area 224, third circuit area 226, fourth circuit area 232, fifth circuit area 234, sixth circuit area 236 corresponds to a logic circuit block, a memory block (e.g., static random access memory (SRAM), dynamic random access memory (DRAM), read-only memory (ROM), or the like), an input/output interface block, an intellectual property (IP) block, a combination thereof, or the like.

In FIG. 2A, first dummy area 242 includes dummy gate structures of a first type, second dummy area 244 includes dummy gate structures of a second type, and third dummy area 246 and fourth dummy area 248 include dummy gate structures of a third type. In some embodiments, different types of dummy gate structures have different removal rates under a given CMP process for forming the gate structures within first circuit area 222, second circuit area 224, third circuit area 226, fourth circuit area 232, fifth circuit area 234, and/or sixth circuit area 236. In some embodiments, a semiconductor device includes two or more types of dummy gate structures having corresponding removal rates under the same CMP process. In FIG. 2A, second dummy area 244 is arranged adjacent to and surrounding second circuit area 224 and fifth circuit area 234, third dummy area 246 is arranged adjacent to and surrounding first circuit area 222, and fourth dummy area 248 is arranged adjacent to and surrounding sixth circuit area 236. Also, in FIG. 2A, first dummy area 242 is arranged adjacent to and surrounding third circuit area 226, fourth circuit area 232, second dummy area 244, third dummy area 246, and fourth dummy area 248. In FIG. 2A, each one of second dummy area 244, third dummy area 246, and fourth dummy area 248 extends from the corresponding circuit area by a distance D. In some embodiments, distance D ranges from 0.1 micrometers (μm) to 1000 μm.

FIG. 2B is a simplified cross-sectional view of semiconductor device 200 taken at a reference line A-A′ in FIG. 2A, in accordance with some embodiments. Components in FIG. 2B that are the same or similar to those in FIG. 2A are given the same reference numbers, and description thereof is thus simplified or omitted.

In FIG. 2B, semiconductor device 200 includes a plurality of functional gate structures 252 within fourth circuit area 232 and over substrate 210, a plurality of functional gate structures 254 within fifth circuit area 234 and over substrate 210, and a plurality of functional gate structures 256 within sixth circuit area 236 and over substrate 210. In FIG. 2B, semiconductor device 200 includes a plurality of dummy gate structures 262 within first dummy area 242, adjacent to fourth circuit area 232, and over substrate 210. In FIG. 2B, semiconductor device 200 further includes a plurality of dummy gate structures 264 within second dummy area 244, adjacent to fifth circuit area 234, and over substrate 210; and a plurality of dummy gate structures 266 within fourth dummy area 248, adjacent to sixth circuit area 236, and over substrate 210. In this non-limiting example, the plurality of dummy gate structures 262 is also adjacent to second dummy area 244 and fourth dummy area 248.

In FIG. 2B, a first average height H1 of the plurality of dummy gate structures 262 is defined based on an average of distances from a lower surface of substrate 210 to upper surfaces of the plurality of dummy gate structures 262 along a height direction (e.g., Z direction). In FIG. 2B, a second average height H2 of the plurality of dummy gate structures 264 is defined based on an average of distances from the lower surface of substrate 210 to upper surfaces of the plurality of dummy gate structures 264 along the height direction. Also, in FIG. 2B, a third average height H3 of the plurality of dummy gate structures 266 is defined based on an average of distances from the lower surface of substrate 210 to upper surfaces of the plurality of dummy gate structures 266 along the height direction.

In this example, based on the corresponding removal rates under the same CMP process, dummy gate structures 262 are configured to control the gate height of functional gate structures 252 in circuit area 232; dummy gate structures 264 are configured to control the gate height of functional gate structures 254 in circuit area 234, and dummy gate structures 266 are configured to control the gate height of functional gate structures 256 in circuit area 236. As a result, an average height of functional gate structures 252 is about first average height H1; an average height of functional gate structures 254 is about second average height H2; and an average height of functional gate structures 256 is about first average height H3. In this example, first average height H1 is less than second average height H2, and second average height H2 is less than third average height H3. In some embodiments, a difference between first average height H1 and second average height H2 ranges from 0.2 nm to 10 nm. In some embodiments, a difference between second average height H2 and third average height H3 ranges from 0.2 nm to 10 nm.

In some embodiments, the plurality of dummy gate structures 262 has a first removal rate in a unit of height per minute under a given CMP process; the plurality of dummy gate structures 264 has a second removal rate in the unit of height per minute under the CMP process; and the plurality of dummy gate structures 266 has a third removal rate in the unit of height per minute under the CMP process. In some embodiments, the second removal rate is at least 5% less than the first removal rate. In some embodiments, the third removal rate is at least 5% less than the second removal rate.

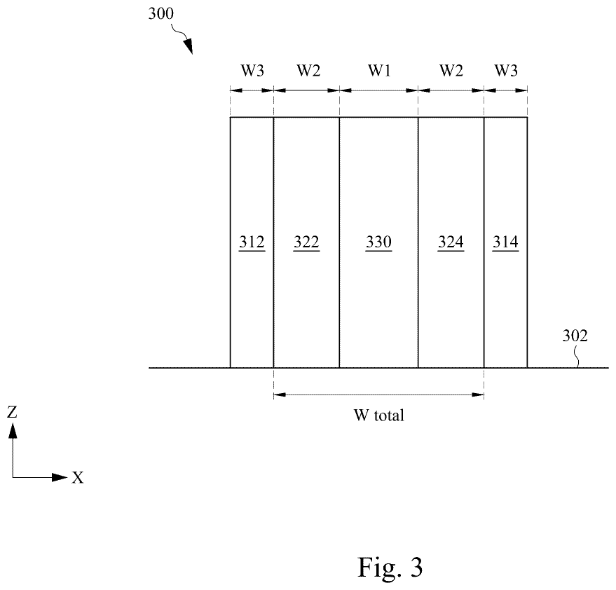

FIG. 3 is an enlarged cross-sectional view of a dummy gate structure 300 over a substrate 302, in accordance with some embodiments. In this non-limiting example, dummy gate structure 300 corresponds to any one of dummy gate structures 262, dummy gate structures 264, or dummy gate structures 266 in FIG. 2B. In FIG. 3, substrate 302 corresponds to substrate 210 in FIGS. 2A and 2B. In this non-limiting example, FIG. 3 is a simplified cross-sectional view taken based on the reference line A-A′ in FIG. 2A.

In some embodiments, each dummy gate of the dummy gate structures in FIG. 2B includes a plurality of portions arranged one next to another along a width direction (e.g., X direction in FIG. 2B). For example, in FIG. 3, dummy gate structure 300 includes two spacer portions 312 and 314, two side portions 322 and 324 sandwiched by spacer portions 312 and 314, and a core portion 330 sandwiched by side portions 322 and 324. In some embodiments, core portion 330 includes one or more layers of tungsten, cobalt, copper, or a combination thereof. In some embodiments, at least one (or all) of side portions 322 and 324 includes one or more layers of titanium, titanium nitride, titanium silicon nitride, titanium aluminide, or a combination thereof. In some embodiments, at least one (or all) of spacer portions 312 and 314 includes silicon oxide or silicon nitride. In some embodiments, the materials used by spacer portions 312 and 314, side portions 322 and 324, and core portion 330 are selected based on the materials used by the functional gate structures (e.g., functional gate structures 252, 254, and/or 256) of the semiconductor device, such that the materials of the dummy gate structures are suitable to be deposited simultaneously with the functional gate structures of the semiconductor device without additional steps and/or additional masks.

In some embodiments, each dummy gate of the dummy gate structures in FIG. 2B includes spacer portions corresponding to spacer portions 312 and 314 that have a spacer portion removal rate in the unit of height per minute under a given CMP process; side portions corresponding to side portions 322 and 324 that have a side portion removal rate in the unit of height per minute under the CMP process; and core portion corresponding to core portion 330 that has a core portion removal rate in the unit of height per minute under the CMP process. In some embodiments, a difference between the spacer portion removal rate and the side portion removal rate are within a 5% difference. In some embodiments, the core portion removal rate is at least 5% less than the side portion removal rate. In some embodiments, the core portion removal rate ranges from 5% to 95% of the side portion removal rate.

In some embodiments, a removal rate of a dummy gate structures is determinable based on adjusting a width W1 of core portion 330, a width W2 of side portion 322 or 324, and/or a width W3 of spacer portion 312 and 314. In some embodiments, width W3 of spacer portion 312 and 314 is not adjustable across all dummy gate structures. In some embodiments, to configure a first dummy gate structure to have a higher removal rate than a second dummy gate structure, a first ratio of a width (i.e., corresponding to W1) of the core portion to a summation (i.e., corresponding to W_total) of the width of the core portion and the widths (i.e., W_total=W1+2*W2) of the side portions of the first dummy gate structure is less than a second ratio of a width (i.e., corresponding to W1) of the core portion to a summation (i.e., corresponding to W_total) of the width of the core portion and the widths (i.e., W_total=W1+2*W2) of the side portions of the second dummy gate structure. That is, the W1/W_total (i.e., the first ratio) of the first dummy gate structure is less than W1/W_total (i.e., the second ratio) of the second dummy gate structure.

In some embodiments, based on the first dummy gate structure corresponding to dummy gate structures 262 and the second dummy gate structure corresponding to dummy gate structures 264, the first ratio ranges from 0 to 15%, and the second ratio ranges from 15% to 25%. In some embodiments, based on the first dummy gate structure corresponding to dummy gate structures 262 and the second dummy gate structure corresponding to dummy gate structures 266, the first ratio ranges from 0 to 15%, and the second ratio ranges from 25% to 50%. In some embodiments, based on the first dummy gate structure corresponding to dummy gate structures 264 and the second dummy gate structure corresponding to dummy gate structures 266, the first ratio ranges from 15% to 25%, and the second ratio ranges from 25% to 50%.

Based on the examples in FIGS. 2A-3, a semiconductor device (e.g., semiconductor device 200) includes a substrate (e.g., substrate 210), a first plurality of functional gate structures (e.g., functional gate structures 252) within a first circuit area (e.g., circuit area 232) over the substrate, a first plurality of dummy gate structures (e.g., dummy gate structures 262) adjacent to the first circuit area over the substrate, a second plurality of functional gate structures (e.g., functional gate structures 254) within a second circuit area (e.g., circuit area 234) over the substrate, and a second plurality of dummy gate structures (e.g., dummy gate structures 264) adjacent to the second circuit area over the substrate. In some embodiments, a first average height (e.g., height H1) of the first plurality of dummy gate structures is different from a second average height (e.g., height H2) of the second plurality of dummy gate structures. In some embodiments, a difference between the first average height and the second average height ranges from 0.2 nm to 10 nm.

In some embodiments, the first plurality of dummy gate structures has a first removal rate in a unit of height per minute under a given CMP process, and the second plurality of dummy gate structures has a second removal rate in the unit of height per minute under the CMP process. In some embodiments, the second removal rate is at least 5% less than the first removal rate.

In some embodiments, each dummy gate of the first plurality of dummy gate structures includes two first spacer portions (e.g., corresponding to spacer portions 312 and 314), two first side portions (e.g., corresponding to side portions 322 and 324) sandwiched by the two first spacer portions, and a first core portion (e.g., corresponding to core portions 330) sandwiched by the two first side portions. In some embodiments, each dummy gate of the second plurality of dummy gate structures includes two second spacer portions (e.g., corresponding to spacer portions 312 and 314), two second side portions (e.g., corresponding to side portions 322 and 324) sandwiched by the two second spacer portions, and a second core portion (e.g., corresponding to core portions 330) sandwiched by the two second side portions.

In some embodiments, the first side portions and the second side portions have a first removal rate in a unit of height per minute under the CMP process, and the first core portion and the second core portion have a second removal rate in the unit of height per minute under the CMP process. In some embodiments, the second removal rate is at least 5% less than the first removal rate. In some embodiments, the first side portion or the second side portion includes one or more layers of titanium, titanium nitride, titanium silicon nitride, titanium aluminide, or a combination thereof. In some embodiments, at least one of the two first core portions or two second core portions includes one or more layers of tungsten, cobalt, copper, or a combination thereof. In some embodiments, at least one of the two first spacer portions or the two second spacer portions includes silicon oxide or silicon nitride.

In some embodiments, a first ratio of a width of the first core portion to a summation of the width of the first core portion and widths of the first side portions is less than a second ratio of a width of the second core portion to a summation of the width of the second core portion and widths of the second side portions. In some embodiments, the first ratio ranges from 0 to 15%, and the second ratio ranges from 15% to 25%. In some embodiments, the first ratio ranges from 0 to 15%, and the second ratio ranges from 25% to 50%. In some embodiments, the first ratio ranges from 15% to 25%, and the second ratio ranges from 25% to 50%.

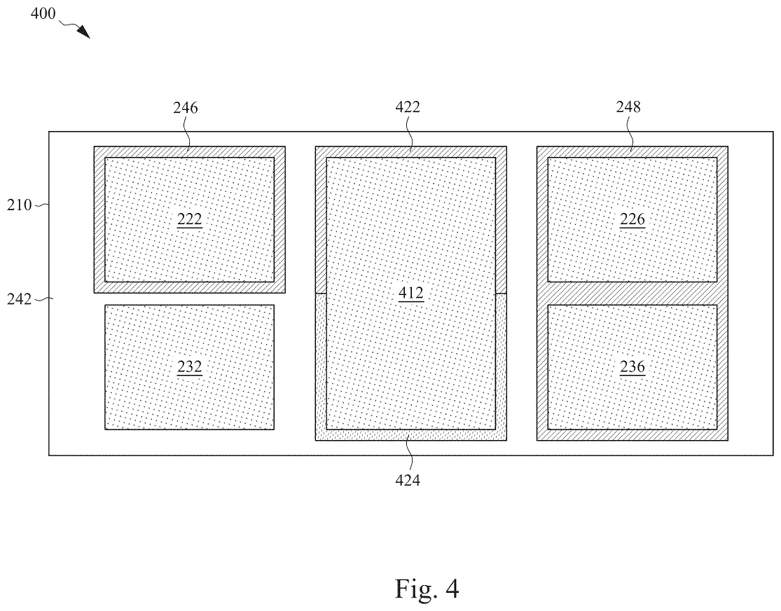

FIG. 4 is a simplified top or plan view of a portion of another semiconductor device 400, in accordance with some embodiments. In some embodiments, semiconductor device 400 is a variation of semiconductor device 200 in FIG. 2A. In some embodiments, components in FIG. 4 that are the same or similar to those in FIG. 2A are given the same reference numbers, and description thereof is simplified or omitted.

In FIG. 4, semiconductor device 400 includes a substrate 210 and a plurality of gate structures over substrate 210. In this example, the plurality of gate structures is arranged within various areas, including circuit areas 222, 226, 232, 236, and 412 and dummy areas 242, 246, 248, 422, and 424. As illustrated with reference to FIG. 2A, each one of circuit areas 222, 226, 232, 236, and 412 corresponds to a logic circuit block, a memory block, an IP block, a combination thereof, or the like. As illustrated with reference to FIG. 2B, each one of circuit areas 222, 226, 232, 236, and 412 includes corresponding functional gate structures; and each one of dummy areas 242, 246, 248, 422, and 424 includes corresponding dummy gate structures.

In some embodiments, one circuit area is adjacent to and surrounded by one dummy area of a same type of dummy gate structures. For example, the dummy gate structures of dummy area 246 are adjacent to and surround circuit area 222; and the dummy gate structures of dummy area 242 are adjacent to and surround circuit area 232. In some embodiments, multiple circuit areas are adjacent to and surrounded by one dummy area of a same type of dummy gate structures. For example, the dummy gate structures of dummy area 248 are adjacent to and surround circuit areas 226 and 236. In some embodiments, a circuit area is adjacent to and surrounded by multiple dummy areas of different types of dummy gate structures. For example, the dummy gate structures of dummy area 422 and the dummy gate structures of dummy area 424 form a ring of dummy gate structures adjacent to and surrounding circuit area 412. In this example, the dummy gate structures of dummy area 422 and the dummy gate structures of dummy area 424 belong to different types of dummy gate structures with different removal rates under a given CMP process.

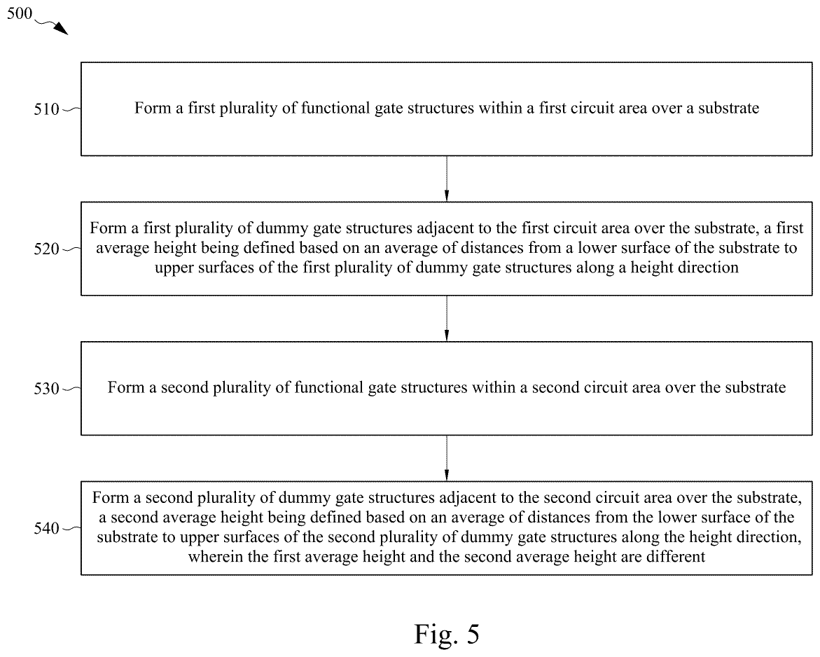

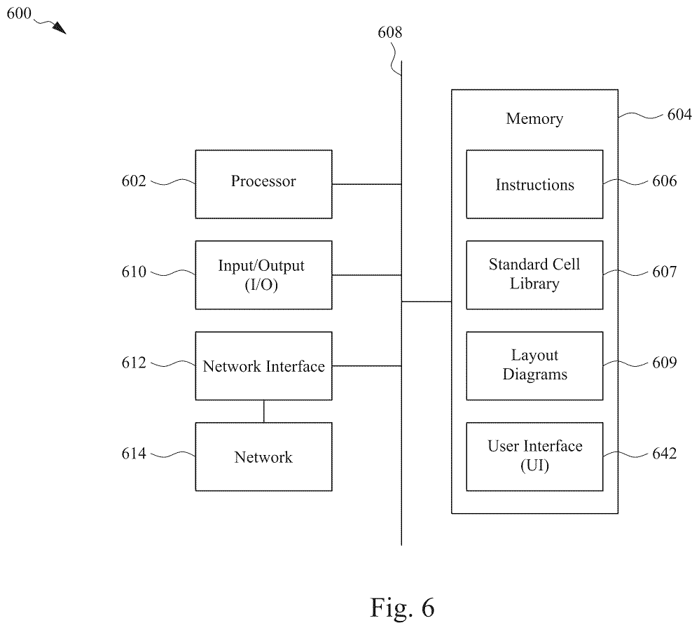

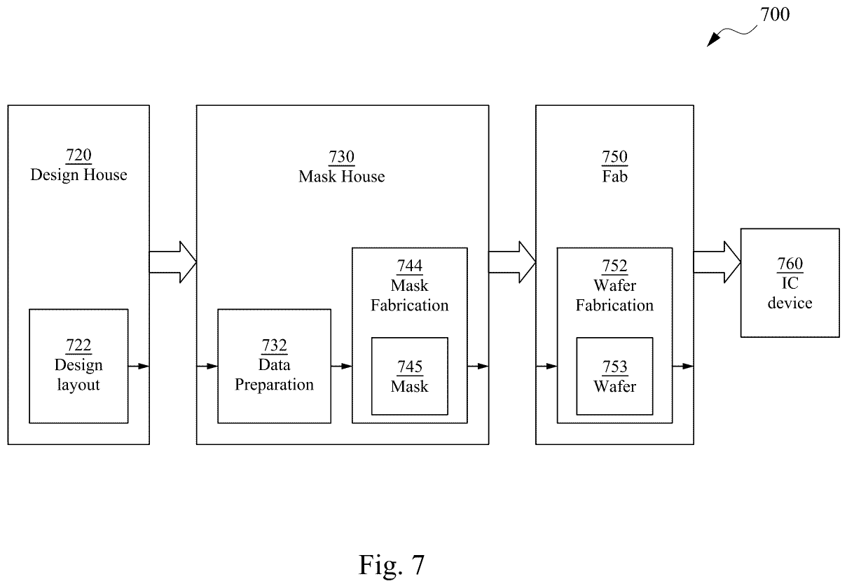

FIG. 5 is a flowchart of a method 500 of manufacturing a semiconductor device, in accordance with some embodiments. In some embodiments, the semiconductor device manufactured based on method 500 corresponds to semiconductor device 200 in FIG. 2A or semiconductor device 400 in FIG. 4 in view of the examples in FIGS. 2B and 3. In some embodiments, various features on which semiconductor device is based are based on one or more layout patterns prepared based on an EDA system 600 as illustrated in FIG. 6. In some embodiments, method 500 corresponds to one or more operations performed based on, in whole or in part, an integrated circuit (IC) manufacturing system 700 as illustrated in FIG. 7. In FIG. 5, method 500 includes blocks 510-540.

At block 510, a first plurality of functional gate structures (e.g., gate structures 252 in FIG. 2B) is formed within a first circuit area (e.g., circuit area 232 in FIG. 2B) over a substrate (e.g., substrate 210 in FIG. 2B).

At block 520, a first plurality of dummy gate structures (e.g., gate structures 262 in FIG. 2B) adjacent to the first circuit area is formed over the substrate. In some embodiments, a first average height (e.g., height H1) is defined based on an average of distances from a lower surface of the substrate to upper surfaces of the first plurality of dummy gate structures along a height direction (e.g., Z direction).

At block 530, a second plurality of functional gate structures (e.g., gate structures 254 in FIG. 2B) is formed within a second circuit area (e.g., circuit area 234 in FIG. 2B) over the substrate.

At block 540, a second plurality of dummy gate structures (e.g., gate structures 264 in FIG. 2B) adjacent to the second circuit area is formed over the substrate. In some embodiments, a second average height (e.g., height H2) is defined based on an average of distances from the lower surface of the substrate to upper surfaces of the second plurality of dummy gate structures along the height direction. In some embodiments, the first average height and the second average height are different. In some embodiments, a difference between the first average height and the second average height ranges from 0.2 nm to 10 nm.

In some embodiments, the formation of the first plurality of functional gate structures, the first plurality of dummy gate structures, the second plurality of functional gate structures, and the second plurality of dummy gate structures are based on performing a CMP process. In some embodiments, the CMP process is performed based on the first plurality of dummy gate structures having a first removal rate in a unit of height per minute under the CMP process. In some embodiments, the CMP process is performed also based on the second plurality of dummy gate structures having a second removal rate in the unit of height per minute under the CMP process. In some embodiments, the second removal rate being at least 5% less than the first removal rate.

In some embodiments, each dummy gate of the first plurality of dummy gate structures includes two first spacer portions (e.g., corresponding to spacer portions 312 and 314 in FIG. 3), two first side portions (e.g., corresponding to side portions 322 and 324 in FIG. 3) sandwiched by the two first spacer portions, and a first core portion (e.g., corresponding to core portion 330 in FIG. 3) sandwiched by the two first side portions. In some embodiments, each dummy gate of the second plurality of dummy gate structures includes two second spacer portions (e.g., corresponding to spacer portions 312 and 314 in FIG. 3), two second side portions sandwiched by the two second spacer portions (e.g., corresponding to side portions 322 and 324 in FIG. 3), and a second core portion sandwiched by the two second side portions (e.g., corresponding to core portion 330 in FIG. 3). In some embodiments, the CMP process for forming the gate structures is performed based on the first side portions and the second side portions having a third removal rate in the unit of height per minute under the CMP process, the first core portion and the first core portion having a fourth removal rate in the unit of height per minute under the CMP process, and the second removal rate is at least 5% less than the first removal rate.

In some embodiments, the formation of the first plurality of functional gate structures, the first plurality of dummy gate structures, the second plurality of functional gate structures, and the second plurality of dummy gate structures are based on forming a plurality of layers of materials and performing the CMP process. In some embodiments, the plurality of layers of materials is arranged such that, after the CMP process, a first ratio of a width of the first core portion to a summation of the width of the first core portion and widths of the first side portions is less than a second ratio of a width of the second core portion to a summation of the width of the second core portion and widths of the second side portions.

In some embodiments, the formation of the plurality of layers of materials is performed based on the first side portion including one or more layers of titanium, titanium nitride, titanium silicon nitride, titanium aluminide, or a combination thereof. In some embodiments, the formation of the plurality of layers of materials is performed based on at least one of the two first core portions including one or more layers of tungsten, cobalt, copper, or a combination thereof. In some embodiments, the formation of the plurality of layers of materials is performed based on at least one of the two first spacer portions including silicon oxide or silicon nitride. In some embodiments, the first ratio ranges from 0 to 15%, and the second ratio ranges from 15% to 25%. In some embodiments, the first ratio ranges from 0 to 15%, and the second ratio ranges from 25% to 50%. In some embodiments, the first ratio ranges from 15% to 25%, and the second ratio ranges from 25% to 50%.

FIG. 6 is a block diagram of an EDA system 600, in accordance with some embodiments. In some embodiments, EDA system 600 includes an automatic placement and routing (APR) system. Methods described herein regarding placement of layout cells are implementable, for example, using EDA system 600, in accordance with some embodiments.

In some embodiments, EDA system 600 is a general purpose computing device including a hardware processor 602 and a memory 604 that includes a non-transitory, computer-readable storage medium. Memory 604, amongst other things, is encoded with, i.e., stores, computer program code 606, i.e., a set of executable instructions. Execution of computer program code 606 (e.g., executable instructions) by hardware processor 602 represents (at least in part) an EDA tool which implements a portion or all of the methods described herein in accordance with one or more embodiments (hereinafter, the noted processes and/or methods).

Processor 602 is electrically coupled to memory 604 via a bus 608. Processor 602 is also electrically coupled to an I/O interface 610 by bus 608. A network interface 612 is also electrically connected to processor 602 via bus 608. Network interface 612 is connected to a network 614, so that processor 602 and memory 604 are capable of connecting to external elements via network 614. Processor 602 is configured to execute computer program code 606 encoded in memory 604 in order to cause system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, memory 604 is an electronic, magnetic, optical, electromagnetic, infrared, and/or a semiconductor system (or apparatus or device). For example, memory 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 604 includes a compact disk-read only memory (CD-ROM), a compact disk-read/write (CD-R/W), and/or a digital video disc (DVD).

In one or more embodiments, memory 604 stores computer program code 606 configured to cause system 600 (where such execution represents (at least in part) the EDA tool) to be usable for performing a portion or all of the noted processes and/or methods. In one or more embodiments, memory 604 also stores information which facilitates performing a portion or all of the noted processes and/or methods. In one or more embodiments, memory 604 stores standard cell library 607 of standard cells including such standard cells as disclosed herein. In one or more embodiments, memory 604 stores one or more layout diagrams 609 corresponding to one or more layouts disclosed herein.

EDA system 600 includes I/O interface 610. I/O interface 610 is coupled to external circuitry. In one or more embodiments, I/O interface 610 includes a keyboard, keypad, mouse, trackball, trackpad, touchscreen, and/or cursor direction keys for communicating information and commands to processor 602. In at least one embodiment, EDA system 600 does not include I/O interface 610.

EDA system 600 also includes network interface 612 coupled to processor 602. Network interface 612 allows system 600 to communicate with network 614, to which one or more other computer systems are connected. Network interface 612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 600.

System 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. EDA system 600 is configured to receive information related to a UI through I/O interface 610. The information is stored in memory 604 as user interface (UI) 642.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 600. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 7 is a block diagram of an integrated circuit (IC) manufacturing system 700, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (fab) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout diagram 722. IC design layout diagram 722 includes various geometrical patterns designed for an IC device 760. The geometrical patterns correspond to patterns of metal, oxide, or semiconductor layers that make up the various components of IC device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes data preparation 732 and mask fabrication 744. Mask house 730 uses IC design layout diagram 722 to manufacture one or more masks 745 (e.g., photomasks based on one or more embodiments in this disclosure) to be used for fabricating the various layers of IC device 760 according to IC design layout diagram 722. Mask house 730 performs mask data preparation 732, where IC design layout diagram 722 is translated into a representative data file (RDF). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for photolithographic implementation effects during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the above description of mask data preparation 732 has been simplified for the purposes of clarity. In some embodiments, data preparation 732 includes additional features such as a logic operation (LOP) to modify the IC design layout diagram 722 according to manufacturing rules. Additionally, the processes applied to IC design layout diagram 722 during data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies (e.g., based on one or more embodiments in this disclosure). In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 750 includes fabrication tools 752 configured to execute various manufacturing operations on semiconductor wafer 753 such that IC device 760 is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout diagram 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

In some aspects, a semiconductor device includes a substrate, a first plurality of functional gate structures within a first circuit area over the substrate, a first plurality of dummy gate structures adjacent to the first circuit area over the substrate, a second plurality of functional gate structures within a second circuit area over the substrate, and a second plurality of dummy gate structures adjacent to the second circuit area over the substrate. A first average height is defined based on an average of distances from a lower surface of the substrate to upper surfaces of the first plurality of dummy gate structures along a height direction. A second average height is defined based on an average of distances from the lower surface of the substrate to upper surfaces of the second plurality of dummy gate structures along the height direction. The first average height and the second average height are different.

In some aspects, a semiconductor device includes a substrate, a first plurality of functional gate structures within a first circuit area over the substrate, a first plurality of dummy gate structures adjacent to the first circuit area over the substrate, a second plurality of functional gate structures within a second circuit area over the substrate, and a second plurality of dummy gate structures adjacent to the second circuit area over the substrate. Each dummy gate of the first plurality of dummy gate structures includes two first spacer portions, two first side portions sandwiched by the two first spacer portions, and a first core portion sandwiched by the two first side portions. Each dummy gate of the second plurality of dummy gate structures includes two second spacer portions, two second side portions sandwiched by the two second spacer portions, and a second core portion sandwiched by the two second side portions. A first ratio of a width of the first core portion to a summation of the width of the first core portion and widths of the first side portions is less than a second ratio of a width of the second core portion to a summation of the width of the first core portion and widths of the second side portions.

In some aspects, a method of manufacturing a semiconductor device includes forming a first plurality of functional gate structures within a first circuit area over a substrate, forming a first plurality of dummy gate structures adjacent to the first circuit area over the substrate, forming a second plurality of functional gate structures within a second circuit area over the substrate, and forming a second plurality of dummy gate structures adjacent to the second circuit area over the substrate. A first average height is defined based on an average of distances from a lower surface of the substrate to upper surfaces of the first plurality of dummy gate structures along a height direction. A second average height is defined based on an average of distances from the lower surface of the substrate to upper surfaces of the second plurality of dummy gate structures along the height direction. The first average height and the second average height are different.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

1. A semiconductor device, comprising:
a substrate;
a first plurality of functional gate structures within a first circuit area over the substrate;
a first plurality of dummy gate structures adjacent to the first circuit area over the substrate, a first average height being defined based on an average of distances from a lower surface of the substrate to upper surfaces of the first plurality of dummy gate structures along a height direction;
a second plurality of functional gate structures within a second circuit area over the substrate; and
a second plurality of dummy gate structures adjacent to the second circuit area over the substrate, a second average height being defined based on an average of distances from the lower surface of the substrate to upper surfaces of the second plurality of dummy gate structures along the height direction,
wherein the first average height and the second average height are different.

2. The semiconductor device of claim 1, wherein
a difference between the first average height and the second average height ranges from 0.2 nanometers (nm) to 10 nm.

3. The semiconductor device of claim 1, wherein
the first plurality of dummy gate structures has a first removal rate in a unit of height per minute under a chemical mechanical polishing (CMP) process;
the second plurality of dummy gate structures has a second removal rate in the unit of height per minute under the CMP process, and
the second removal rate is at least 5% less than the first removal rate.

4. The semiconductor device of claim 1, wherein
each dummy gate of the first plurality of dummy gate structures includes a first plurality of portions arranged one next to another along a width direction, and
each dummy gate of the second plurality of dummy gate structures includes a second plurality of portions arranged one next to another along the width direction.

5. The semiconductor device of claim 4, wherein
the first plurality of portions includes two first spacer portions, two first side portions sandwiched by the two first spacer portions, and a first core portion sandwiched by the two first side portions,
the first core portion includes one or more layers of tungsten, cobalt, copper, or a combination thereof,
at least one of the two first side portions includes one or more layers of titanium, titanium nitride, titanium silicon nitride, titanium aluminide, or a combination thereof, and
at least one of the two first spacer portions includes silicon oxide or silicon nitride.

6. The semiconductor device of claim 4, wherein
the first plurality of portions includes two first spacer portions, two first side portions sandwiched by the two first spacer portions, and a first core portion sandwiched by the two first side portions,
the second plurality of portions includes two second spacer portions, two second side portions sandwiched by the two second spacer portions, and a second core portion sandwiched by the two second side portions,
the first side portions and the second side portions have a third removal rate in a unit of height per minute under a chemical mechanical polishing (CMP) process,
the first core portion and the second core portion have a fourth removal rate in the unit of height per minute under the CMP process,
the fourth removal rate is at least 5% less than the third removal rate, and
a first ratio of a width of the first core portion to a summation of the width of the first core portion and widths of the first side portions is less than a second ratio of a width of the second core portion to a summation of the width of the second core portion and widths of the second side portions.

7. The semiconductor device of claim 6, wherein
the first ratio ranges from 0 to 15%, and the second ratio ranges from 15% to 25%,
the first ratio ranges from 0 to 15%, and the second ratio ranges from 25% to 50%, or
the first ratio ranges from 15% to 25%, and the second ratio ranges from 25% to 50%.

8. The semiconductor device of claim 1, wherein
the first plurality of dummy gate structures is adjacent to and surrounding the first circuit area,
the second plurality of dummy gate structures is adjacent to and surrounding the second circuit area,
the first plurality of dummy gate structures is adjacent to and surrounding the second plurality of dummy gate structures, or
a combination thereof.

9. The semiconductor device of claim 1, further comprising:
a third plurality of functional gate structures within a third circuit area over the substrate,
wherein
the first plurality of dummy gate structures is adjacent to and surrounding the first circuit area and the third circuit area.

10. The semiconductor device of claim 1, further comprising:
a third plurality of dummy gate structures adjacent to the first circuit area over the substrate, a third average height being defined based on an average of distances from the lower surface of the substrate to upper surfaces of the third plurality of dummy gate structures along the height direction,
wherein
the first average height and the third average height are different.

11. The semiconductor device of claim 10, wherein
the first plurality of dummy gate structures and the third plurality of dummy gate structures forming a ring of dummy gate structures adjacent to and surrounding the first circuit area.

12. A semiconductor device, comprising:
a substrate;
a first plurality of functional gate structures within a first circuit area over the substrate;
a first plurality of dummy gate structures adjacent to the first circuit area over the substrate;
a second plurality of functional gate structures within a second circuit area over the substrate; and
a second plurality of dummy gate structures adjacent to the second circuit area over the substrate,
wherein
each dummy gate of the first plurality of dummy gate structures includes two first spacer portions, two first side portions sandwiched by the two first spacer portions, and a first core portion sandwiched by the two first side portions,
each dummy gate of the second plurality of dummy gate structures includes two second spacer portions, two second side portions sandwiched by the two second spacer portions, and a second core portion sandwiched by the two second side portions, and
a first ratio of a width of the first core portion to a summation of the width of the first core portion and widths of the first side portions is less than a second ratio of a width of the second core portion to a summation of the width of the second core portion and widths of the second side portions.

13. The semiconductor device of claim 12, wherein
the first side portions and the second side portions have a first removal rate in a unit of height per minute under a chemical mechanical polishing (CMP) process,
the first core portion and the first-second core portion have a second removal rate in the unit of height per minute under the CMP process, and
the second removal rate is at least 5% less than the first removal rate.

14. The semiconductor device of claim 12, wherein
the first core portion or the second core portion includes one or more layers of tungsten, cobalt, copper, or a combination thereof,
at least one of the two first side portions or the two second side portions includes one or more layers of titanium, titanium nitride, titanium silicon nitride, titanium aluminide, or a combination thereof, and
at least one of the two first spacer portions or the two second spacer portions includes silicon oxide or silicon nitride.

15. The semiconductor device of claim 12, wherein
the first ratio ranges from 0 to 15%, and the second ratio ranges from 15% to 25%,
the first ratio ranges from 0 to 15%, and the second ratio ranges from 25% to 50%, or
the first ratio ranges from 15% to 25%, and the second ratio ranges from 25% to 50%.

16. A method of manufacturing a semiconductor device, comprising:
forming a first plurality of functional gate structures within a first circuit area over a substrate;
forming a first plurality of dummy gate structures adjacent to the first circuit area over the substrate, a first average height being defined based on an average of distances from a lower surface of the substrate to upper surfaces of the first plurality of dummy gate structures along a height direction;
forming a second plurality of functional gate structures within a second circuit area over the substrate; and
forming a second plurality of dummy gate structures adjacent to the second circuit area over the substrate, a second average height being defined based on an average of distances from the lower surface of the substrate to upper surfaces of the second plurality of dummy gate structures along the height direction,
wherein the first average height and the second average height are different.

17. The method of claim 16, wherein
a difference between the first average height and the second average height ranges from 0.2 nanometers (nm) to 10 nm.

18. The method of claim 16, wherein
the forming the first plurality of functional gate structures, the forming the first plurality of dummy gate structures, the forming the second plurality of functional gate structures, and the forming the second plurality of dummy gate structures are based on performing a chemical mechanical polishing (CMP) process, and
the CMP process is performed based on
the first plurality of dummy gate structures having a first removal rate in a unit of height per minute under the CMP process;
the second plurality of dummy gate structures having a second removal rate in the unit of height per minute under the CMP process, and
the second removal rate being at least 5% less than the first removal rate.

19. The method of claim 18, wherein
each dummy gate of the first plurality of dummy gate structures includes two first spacer portions, two first side portions sandwiched by the two first spacer portions, and a first core portion sandwiched by the two first side portions,
each dummy gate of the second plurality of dummy gate structures includes two second spacer portions, two second side portions sandwiched by the two second spacer portions, and a second core portion sandwiched by the two second side portions, and
the CMP process is performed based on
the first side portions and the second side portions having a third removal rate in the unit of height per minute under the CMP process,
the first core portion and the second core portion having a fourth removal rate in the unit of height per minute under the CMP process, and
the fourth removal rate is at least 5% less than the third removal rate.

20. The method of claim 19, further comprising:
the forming the first plurality of functional gate structures, the forming the first plurality of dummy gate structures, the forming the second plurality of functional gate structures, and the forming the second plurality of dummy gate structures are based on forming a plurality of layers of materials and performing a chemical mechanical polishing (CMP) process,
wherein the plurality of layers of materials is arranged such that, after the CMP process, a first ratio of a width of the first core portion to a summation of the width of the first core portion and widths of the first side portions is less than a second ratio of a width of the second core portion to a summation of the width of the second core portion and widths of the second side portions.
